(19) United States
(12) Patent Application Publication
(10) Pub. No.: US 2016/0126246 A1
(43) Pub. Date: May 5, 2016

(54) INTEGRATED CIRCUIT DEVICES HAVING METAL-INSULATOR-SILICON CONTACT AND METHODS OF FABRICATING THE SAME

(71) Applicant: Sungsam LEE, Yongin-si (KR)

(72) Inventor: Sungsam LEE, Yongin-si (KR)

(21) Appl. No.: 14/815,316

(22) Filed: Jul. 31, 2015

(30) Foreign Application Priority Data
Oct. 29, 2014 (KR) 10-2014-0148528

(51) Int. Cl. H01L 27/108; H01L 29/45; H01L 29/08; H01L 29/51

(52) U.S. Cl. CPC H01L 27/10814; H01L 27/10897; H01L 29/517; H01L 29/45; H01L 29/0847

(57) ABSTRACT

Integrated circuit devices and methods of forming the devices are provided. The devices may include an active area, a gate electrode in the active area and a source/drain area adjacent a side of the gate electrode in the active area. The source/drain area may include a doped semiconductor material. The devices may also include an interlayer insulating layer on the active area, and the interlayer insulating layer may include a recess exposing an upper surface of the source/drain area. The devices may further include a conductive plug that is in the recess and includes a first metal and an insulating layer that is in the recess and includes a second metal. The insulating layer may be between the upper surface of the source/drain area and a lower surface of the conductive plug and may contact the doped semiconductor material.

### CROSS-REFERENCE TO RELATED APPLICATION

This application claims priority under 35 U.S.C. §119 to Korean Patent Application No. 10-2014-0148528 filed on Oct. 29, 2014, the disclosure of which is hereby incorporated by reference in its entirety.

### BACKGROUND

Embodiments of the inventive concept relate to integrated circuit devices (e.g., memory device) in which a low resistance insulating layer having a small conduction band offset with respect to a silicon substrate and a conductive metal are stacked therebetween so that a process margin may be ensured, a contact resistance may be reduced, and a leakage current may be possibly minimized.

With the trend of an increase of a degree of integration in the memory devices (e.g., DRAM), patterns disposed in memory cells have been further miniaturized.

Specifically, when a buried contact which electrically connects a transistor to a capacitor is formed of polysilicon, a small size of the buried contact may cause defects such as seam defects, a poly void, a shortage of impurity concentration of polysilicon may occur.

Various techniques for improving this problem have been proposed.

### SUMMARY

A memory device may include an active area including a source/drain area in a substrate, a gate line crossing the active area, a low resistance insulating layer contacting an upper surface of the source/drain area and a contact on the upper surface of the source/drain area. The contact may contact the low resistance insulating layer and may include a conductive metal. The device may also include a storage capacitor electrically connected to the contact.

In various embodiments, the low resistance insulating layer may include a metal oxide having a small conduction band offset with respect to the source/drain area.

According to various embodiments, the low resistance insulating layer may include titanium oxide (TiO₂), tantalum oxide (Ta₂O₅), or zirconium oxide (ZnO).

According to various embodiments, the device may further include a barrier layer between the low resistance insulating layer and the contact.

According to various embodiments, the low resistance insulating layer may be between a lower surface of the contact and the upper surface of the source/drain area.

In various embodiments, the upper surface of the source/drain area contacting the low resistance insulating layer may be devoid of silicide.

According to various embodiments, the device may further include a landing pad between the storage capacitor and the contact.

According to various embodiments, the landing pad may be contiguous with the contact and may have a width greater than a width of the contact when viewed in cross section.

In various embodiments, the low resistance insulating layer may contact the contact and the landing pad.

In various embodiments, the source/drain area may include a first source/drain area adjacent a first side of the gate line, and the low resistance insulating layer may include a first low resistance insulating layer contacting an upper surface of the first source/drain area. The device may further include a second source/drain area adjacent a second side of the gate line, a bit line plug on the second source/drain area and a second low resistance insulating layer between the bit line plug and the second source/drain area. The bit plug may include a conductive metal.

According to various embodiments, the device may also include a bit line, the bit line plug and the bit line may have a unitary structure, and the second low resistance insulating layer may contact the bit line plug and the bit line.

In various embodiments, a portion of the second low resistance insulating layer may contact both the bit plug and the second source/drain area.

In various embodiments, the device may additionally include an isolation layer surrounding the active area and a gate trench crossing the active area and the isolation layer.

According to various embodiments, a depth of the gate trench crossing the isolation layer may be greater than a depth of the gate trench crossing the active area. The gate line may be in the gate trench.

According to various embodiments, the device may further include a peripheral active area in a peripheral area of the substrate and a gate electrode crossing the peripheral active area. The peripheral active area may include a peripheral source/drain area.

In various embodiments, the device may also include a silicide layer in the peripheral source/drain area of the peripheral area.

According to various embodiments, the device may further include a peripheral active area in a peripheral area of the substrate. The peripheral active area may include a peripheral source/drain area and a silicide layer in the peripheral source/drain area.

According to various embodiments, the device may also include a gate electrode crossing the peripheral active area.

In various embodiments, the device may also include a source/drain contact contacting the silicide layer in the peripheral source/drain area.

A memory device may include a substrate, at least one active area including a first source/drain area and a second source/drain area in the substrate, a gate line crossing the active area, a first low resistance insulating layer contacting the first source/drain area, a bit line plug contacting the first low resistance insulating layer and including a conductive metal, a bit line contacting the bit line plug and crossing the gate line, a second low resistance insulating layer contacting the second source/drain area and a buried contact contacting the second low resistance insulating layer and including a conductive metal.

In various embodiments, the bit line plug and the bit line may have a unitary structure, and the first low resistance insulating layer may contact the bit line plug and the bit line.

According to various embodiments, the first low resistance insulating layer may contact an upper surface of the first source/drain area, and the second low resistance insulating layer may be between a bottom surface of the buried contact and an upper surface of the second source/drain area.

In various embodiments, the device may also include further comprising a landing pad on an end of the buried contact. The landing pad and the buried contact may have a unitary structure, and the landing pad may extend in a lateral direction.

According to various embodiments, the second low resistance insulating layer may contact the buried contact and the landing pad.

In various embodiments, the second low resistance insulating layer may be only on an upper surface of the second source/drain area.

A memory device may include a substrate including a source/drain area, a low resistance insulating layer contacting the source/drain area and a pillar-shaped contact electrode contacting the low resistance insulating layer and including a conductive metal.

An integrated circuit device may include an active area in a substrate, a gate electrode in the active area, a source/drain area adjacent a side of the gate electrode in the active area and an interlayer insulating layer on the active area. The source/drain area may include a doped semiconductor material, and the interlayer insulating layer may include a recess that exposes an upper surface of the source/drain area. The device may also include a conductive plug that is in the recess and includes a first metal and an insulating layer that is in the recess and includes a second metal. The insulating layer may extend between the upper surface of the source/drain area and a lower surface of the conductive plug and may contact the doped semiconductor material.

In various embodiments, the insulating layer may include titanium oxide (TiO₂), tantalum oxide (Ta₂O₅), or zirconium oxide (ZnO).

According to various embodiments, a thickness of the insulating layer in a vertical direction that is perpendicular to the upper surface of the source/drain area may be less than about 2 nm.

According to various embodiments, the source/drain area may include a first source/drain area adjacent a first side of the gate electrode, and the device may further include a second source/drain area adjacent a second side of the gate electrode. A dopant concentration of the first source/drain area may be lower than a dopant concentration of the second source/drain area.

In various embodiments, the device may further include a storage capacitor including an electrode. The conductive plug may be electrically connected to the electrode of the storage capacitor.

According to various embodiments, the upper surface of the source/drain area may be devoid of silicide.

According to various embodiments, the source/drain area may include a first source/drain area adjacent a first side of the gate electrode, the recess may include a first recess that is in the interlayer insulating layer and exposes an upper surface of the first source/drain area, the conductive plug may include a first conductive plug in the first recess, the insulating layer may include a first insulating layer that may be in the first recess. The device may further include a second source/drain area adjacent a second side of the gate electrode, a second recess that is in the interlayer insulating layer and exposes an upper surface of the second source/drain area, a second conductive plug that is in the second recess and may include a third metal and a second insulating layer that is in the second recess and may include a fourth metal. The second insulating layer may extend between the upper surface of the second source/drain area and a lower surface of the second conductive plug and may contact the upper surface of the second source/drain area.

In various embodiments, the second insulating layer may include titanium oxide (TiO₂), tantalum oxide (Ta₂O₅), or zirconium oxide (ZnO).

According to various embodiments, the device may further include a bit line. The second conductive plug may be electrically connected to the bit line.

In various embodiments, the device may further include a barrier layer that may include a barrier metal and may be between the insulating layer and the conductive plug.

According to various embodiments, the insulating layer may be on an inner sidewall of the recess.

### BRIEF DESCRIPTION OF THE DRAWINGS

The foregoing and other features and advantages of the inventive concept will be discussed with reference to the drawings illustrating embodiments of the inventive concept. Like reference characters refer to the same parts throughout the different views. The drawings are not necessarily to scale, emphasis instead being placed upon illustrating the principles of the inventive concept. In the drawings:

FIG. 1 is a plan view of a cell area and a peripheral area of a memory device in accordance with some embodiments of the inventive concept;

FIGS. 2A, 2B, and 2C are cross-sectional views of a memory device taken along the lines I-I′, II-II′, and III-III′ of FIG. 1, respectively;

FIG. 3A is a graph showing resistivity of metal-semiconductor (MS) contacts and metal-insulator-semiconductor (MIS) contacts, of which Schottky barrier heights (SHB) are different, according to a doping concentration thereof;

FIG. 3B is a graph showing a change of contact resistivity according to a thickness of an insulating material layer;

FIG. 3C is a graph showing a contact resistance characteristic of an MIS contact according to a thickness of an insulating material layer in accordance with some embodiments of the inventive concept;

FIGS. 4A and 4B are cross-sectional views of a memory device taken along the lines I-I′ and II-II′ of FIG. 1 and FIG. 4C is a cross-sectional view of the memory device taken along the line III-III′ of FIG. 1;

FIG. 5A is an enlarged view of a part F1 in FIG. 2A, and FIG. 5B is an enlarged view of a part F2 in FIG. 4A;

FIGS. 6A and 6B are enlarged views of a part F3 in FIG. 2A;

FIG. 6C is a plan view showing arrangements of the buried contact, the landing pad, and the first storage electrode;

FIGS. 7A, 8A, 9A, 10A and 11A are cross-sectional views of a memory device taken along the line I-I′ of FIG. 1, FIGS. 7B, 8B, 9B, 10B and 11B are cross-sectional views of the memory device taken along the line II-II′ of FIG. 1, and FIGS. 8C, 9C, 10C and 11C are cross-sectional views of the memory device taken along lines I-I′, II-II′ and III-III′ of FIG. 1;

FIGS. 12A, 13A and 14A, FIGS. 12B, 13B and 14B, and FIGS. 13C and 14C are cross-sectional views of a memory device taken along the lines I-I′, II-II′, and III-III′ of FIG. 1, respectively;

FIG. 15 is a module including a memory device according to some embodiments of the inventive concept;

FIG. 16 is a block diagram of an electronic system including a memory device according to some embodiments of the inventive concept; and

FIG. 17 is a schematic block diagram of an electronic system including a memory device according to some embodiments of the inventive concept.

### DETAILED DESCRIPTION OF THE EMBODIMENTS

Various embodiments will now be described more fully with reference to the accompanying drawings in which some embodiments are shown. These inventive concept may, however, be embodied in different forms and should not be construed as limited to the embodiments set forth herein. Rather, these embodiments are provided so that this disclosure is thorough and complete and fully conveys the inventive concept to those skilled in the art.

The terminology used herein is for the purpose of describing particular embodiments only and is not intended to be limiting of the inventive concept. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, steps, operations, elements, and/or components, but do not preclude the presence or addition of one or more other features, steps, operations, elements, components, and/or groups thereof.

It will be understood that when an element or layer is referred to as being “on,” “connected to,” or “coupled to” another element or layer, it can be directly on, connected, or coupled to the other element or layer or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items.

Spatially relative terms, such as “beneath,” “below,” “lower,” “above,” “upper,” and the like, may be used herein for ease of description in describing one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein may be interpreted accordingly.

Some embodiments of the inventive concept will be described with reference to cross-sectional views and/or plan views, which are ideal views. Thicknesses of layers and areas are exaggerated for effective description of the technical contents in the drawings. Forms of the embodiments may be modified by the manufacturing technology and/or tolerance. Therefore, the embodiments of the inventive concept are not intended to be limited to illustrated specific forms, and include modifications of forms generated according to manufacturing processes. For example, an etching area illustrated at a right angle may be round or have a predetermined curvature. Therefore, areas illustrated in the drawings may have overview properties, and shapes of the areas are illustrated special forms of the areas of a device, and are not intended to be limited to the scope of the inventive concept.

Hereinafter, like reference numerals in the drawings denote like elements. Therefore, although like reference numerals or similar reference numerals are not mentioned or described in the drawing, it will be described with reference to the other drawings. Further, although reference numerals are not illustrated, it will be described with reference to the other drawings.

Terms such as “front side,” and “back side” may be used in a relative sense herein to facilitate easy understanding of the inventive concept. Accordingly, “front side,” and “back side” may not refer to any specific direction, location, or component, and may be used interchangeably. For example, “front side” may be interpreted as “back side” and vice versa. Also, “front side” may be expressed as “first side,” and “back side” may be expressed as “second side,” and vice versa. However, “front side,” and “back side” cannot be used interchangeably in the same embodiment.

The term “near” is intended to mean that one among two or more components is located within relatively close proximity of a certain other component. For example, it should be understood that when a first end is near a first side, the first end may be closer to the first side than a second end, or the first end may be closer to the first side than to a second side.

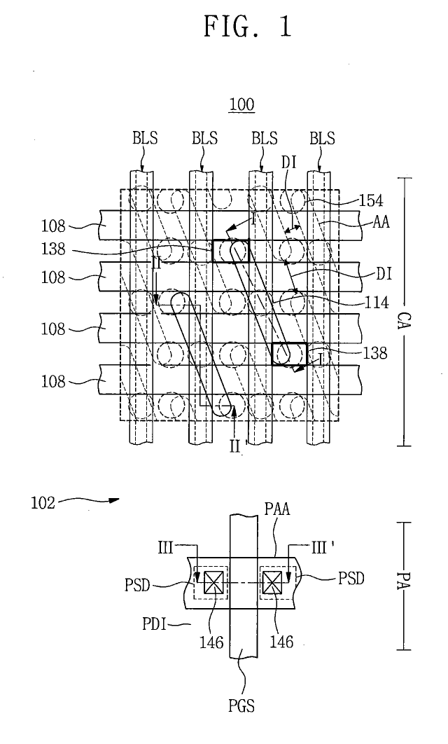

FIG. 1 is a plan view of a cell area and a peripheral area of a memory device in accordance with some embodiments of the inventive concept.

Referring to FIG. 1, the memory device 100 in accordance with some embodiments of the inventive concept may include a substrate 102, gate line stacks 108, bit plugs 114, bit line stacks BLS, buried contacts 138, peripheral gate electrode stacks PGS, and source/drain contacts 146.

The substrate 102 may include a cell area CA and a peripheral area PA. The substrate 102 may include a silicon substrate or a silicon germanium substrate. The cell area CA may include bar-shaped active areas AA and device isolation areas DI each which separate the active areas AA. Further, the peripheral area PA may include peripheral active areas PAA and peripheral device isolation areas PDI.

In the cell area CA, the gate line stacks 108 may extend in a first direction through the active areas AA and the device isolation area DI, and may be spaced apart from each other in a second direction that is perpendicular to the first direction. The bit line stacks BLS may extend in the second direction, and may be spaced apart from each other in the first direction. The gate line stacks 108 may be buried in the substrate 102. The bit line stacks BLS may be electrically connected to the bit plug 114. The bit line stacks BLS and the bit plug 114 may be separately formed or may be formed in one body. In some embodiments, the bit line stacks BLS and the bit plug 114 may have a unitary structure and thus may be contiguous each other. The buried contacts 138 may be formed in an area which are surrounded by two adjacent bit line stacks BLS and two adjacent gate line stacks 108. Each of the buried contacts 138 may have a rectangular shape in a plan view.

In the peripheral area PA, the peripheral gate electrode stack PGS may be formed to cross the peripheral active area PAA, and the source/drain contacts 146 may be formed in portions of the peripheral active area PAA which does not contact the peripheral gate electrode stack PGS. The peripheral active area PAA which contacts the source/drain contacts 146 may be a peripheral source/drain areas PSD which are doped with impurities. A silicide layer may be further formed in the peripheral source/drain area PSD. For example, the peripheral gate electrode stacks PGS, the peripheral active area PAA including the peripheral source/drain areas PSD, and the source/drain contacts 146 may be included in a switching device.

As the memory device 100 is highly integrated, a number of defects may occur in the buried contact 138 that is formed of polysilicon. For example, the buried contact 138 may include polysilicon including impurities, and seam defects, a poly void, a shortage of impurity concentration, or the like may occur as a size of the buried contact 138 decreases.

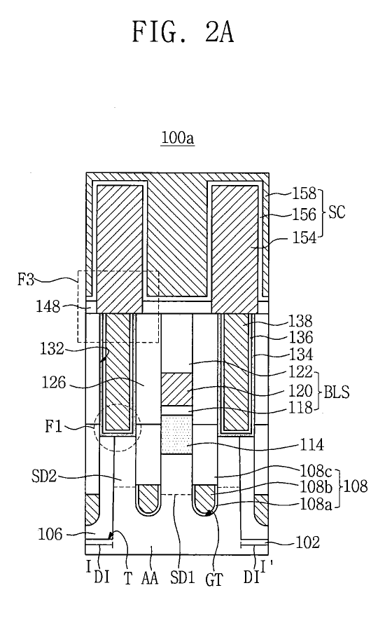

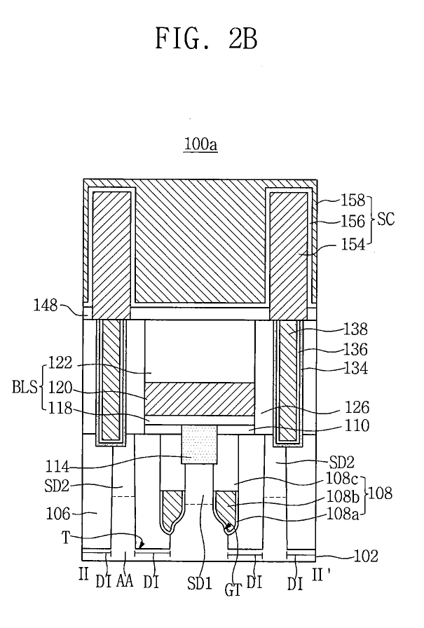

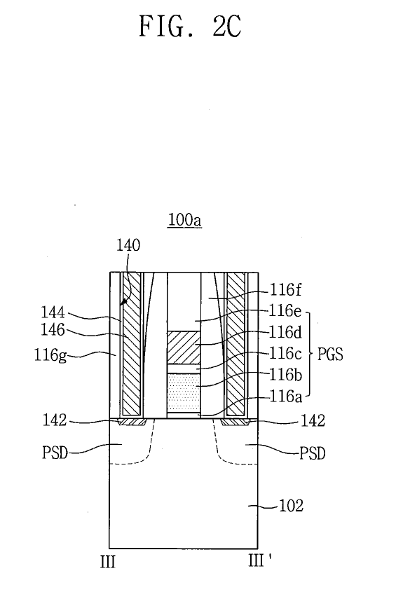

Hereinafter, a memory device in accordance with some embodiments of the inventive concept will be described with reference to FIGS. 2A to 2C.

FIGS. 2A, 2B, and 2C are cross-sectional views of a memory device taken along the lines I-I′, II-II′, and III-III′ of FIG. 1, respectively.

Referring to FIGS. 1, 2A, 2B, and 2C, the memory device 100a in accordance with some embodiments of the inventive concept may include a substrate 102 including a cell area CA and a peripheral area PA. The cell area CA may include gate line stacks 108, bit plugs 114, bit line stacks BLS, a low resistance insulating layer 134, buried contacts 138, and storage capacitors SC which contact the buried contacts 138. The peripheral area PA may include peripheral gate electrode stacks PGS and source/drain contacts 146.

The cell area CA may include an active area AA and a device isolation area DI which defines a boundary of the active area AA. In some embodiments, the device isolation area DI may surround the active area AA. Trenches T may be formed by recessing a surface of the substrate 102, and an isolation layer 106 may fill the trench T in the device isolation area DI. For example, the active area AA may have a bar shape which extends in one direction, and the bar-shaped active area AA may be disposed in the cell area CA to have a constant gradient. For example, the active area AA may include a first source/drain area SD1 located at a center of the active area AA and second source/drain areas SD2 located at one side and another side of the first source/drain area SD1, respectively. The substrate 102 may include, for example, a silicon substrate or a silicon germanium substrate. The isolation layer 106 may include, for example, silicon oxide (SiO₂).

Gate trenches GT may be formed to cross the device isolation area DI and the active area AA. In this case, depths of the gate trenches GT may be formed in the device isolation area DI and the active area AA differently. For example, the depth of the gate trench GT in the device isolation area DI may be greater than that of the gate trench GT in the active area AA.

The adjacent gate line stacks 108 may cross any bar-shaped active area AA. Portions of the active area AA, which are not crossed by the gate line stack 108, may be the first source/drain area SD1 and the second source/drain areas SD2. The first source/drain area SD1 may be located between two adjacent gate line stacks 108, and the second source/drain areas SD2 may be located at other areas, respectively. The first source/drain area SD1 may be adjacent a first side of one of the gate line stacks 108, and the second source/drain area SD2 may be adjacent a second side of the one of the gate line stacks 108. The second source/drain areas SD2 each may include doping impurities at a concentration lower than that of the first source/drain area SD1. A low dopant concentration in the second source/drain areas SD2 may reduce a leakage current. For example, the impurities may include N-type impurities. In some embodiments, the first source/drain area SD1 and the second source/drain area SD2 may include a doped semiconductor material and may be devoid of silicide. In some embodiments, an upper surface of the second source/drain area SD2 may include be devoid of silicide, and the low resistance insulating layer 134 may contact the upper surface of the second source/drain area SD2.

The gate line stacks 108 each may include a gate insulating layer 108a which covers an inner wall of the gate trench GT, a gate line 108b which contacts the gate insulating layer 108a and fills a part of the gate trench GT, and a gate capping layer 108c which is formed on the gate line 108b and fills the remainder of the gate trench GT. The gate line 108b may fill a half of the gate trench GT or less. An upper surface of the gate capping layer 108c may be located at the same level as upper surfaces of the active area AA and the isolation layer 106. The gate insulating layer 108a may include silicon oxide (SiO₂) or insulating materials having a high dielectric constant such as iridium oxide (IrO₂), and hafnium oxide (HfO₂). The gate line 108b may include a conductive material such as tungsten (W). The gate capping layer 108c may include an insulating material such as silicon nitride (SiNₓ).

The bit line stacks BLS each may include a bit line barrier layer 118, a bit line 120, and a bit line capping layer 122, which are sequentially stacked. Bit line side wall spacers 126 which cover side surfaces of the bit line barrier layer 118, the bit line 120, and the bit line capping layer 122 may be further formed. The peripheral gate electrode stacks PGS may be formed in the peripheral area PA. The peripheral gate electrode stacks PGS each may include a gate insulating layer 116a, a first gate 116b, a gate barrier layer 116c, a second gate 116d, and a gate electrode capping layer 116e. Peripheral gate electrode side wall spacers 116f which cover side surfaces of the peripheral gate electrode stacks PGS may be further formed. A protection layer 116g may cover the peripheral gate electrode side wall spacers 116f.

Source/drain contact holes 140 may be formed through the protection layer 116g, and a bottom of the source/drain contact hole 140 may be the surface of the substrate 102. In the bottoms of the source/drain contact holes 140, impurities may be included in peripheral source/drain areas PSD. The peripheral source/drain areas PSD each may include N-type impurities or P-type impurities. A silicide layer 142 may be formed in the peripheral source/drain areas PSD, and may include the same type of impurities as the peripheral source/drain area PSD. The source/drain contacts 146 may contact the peripheral source/drain areas PSD and fill the source/drain contact holes 140.

The bit line barrier layer 118 and the gate barrier layer 116c each may include, for example, titanium (Ti), tantalum (Ta), tantalum nitride (TaN), tungsten nitride (WN), titanium nitride (TiN), or another barrier metal. The bit line 120 and the second gate 116d each may include, for example, tungsten (W), aluminum (Al), copper (Cu), or nickel (Ni), and the bit line capping layer 122 and the gate electrode capping layer 116e each may include, for example, silicon nitride (SiNₓ). The bit line side wall spacer 126 and the peripheral gate electrode side wall spacer 116f each may include, for example, silicon nitride (SiNₓ). The peripheral gate electrode stack PGS may be formed using a process forming the bit plug 114 and the bit line stack BLS or may be formed using different processes. For example, the bit line side wall spacer 126 and the peripheral gate electrode side wall spacer 116f may be formed using different processes.

A first interlayer insulating layer 110 may be formed under the bit line stacks BLS. The bit plug 114 may pass through the first interlayer insulating layer 110 and may contact a recessed surface of the first source/drain area SD1. The bit plug 114 may be physically and electrically connected to the first source/drain area SD1 and the bit line stack BLS. For example, first interlayer insulating layer 110 may include silicon oxide (SiO₂), and the bit plug 114 may include a conductive material such as polysilicon, a metal, or a metal silicide.

Buried contact holes 132 may be formed to expose a surface (e.g., an upper surface) of the second source/drain areas SD2. An inner wall of the buried contact hole 132 may be a side surface of the bit line side wall spacer 126. The low resistance insulating layer 134 may be conformally formed along the surface of the second source/drain area SD2 and the inner wall of the buried contact hole 132. In some embodiments, the low resistance insulating layer 134 may contact the surface of the second source/drain area SD2. Specifically, the low resistance insulating layer 134 may contact the doped semiconductor material in the second source/drain area SD2. The buried contact 138 may fill the buried contact hole 132 to contact the low resistance insulating layer 134. A buried contact barrier layer 136 may be interposed between the low resistance insulating layer 134 and the buried contact 138.

Since the low resistance insulating layer 134 is between the silicon substrate 102 and the buried contact 138, the buried contact 138 may be formed of a conductive metal material. When the conductive metal is used for the buried contacts 138, problems caused by forming the buried contacts 138 included in the highly integrated semiconductor devices using polysilicon may be reduced or possibly minimized.

Polysilicon has been used in the formation of the buried contact 138. As appreciated by the present inventors, with the increase of a degree of integration of the semiconductor device, a size of the buried contact 138 is further minimized, and a Schottky contact characteristic, or the like caused by poly void, seam defects, and shortage of impurities concentration included in the polysilicon may occur. In order to reduce this problem, the buried contact 138 may be formed of a metal material, however, a Fermi level pinning phenomenon in which a threshold voltage of the device is increased by a Schottky barrier between the metal material layer and the silicon substrate 102 may occur. In order to reduce this problem, a doping concentration of the second source/drain area SD2 may be increased, but a leakage current may be increased. However, when a low resistance insulating material layer (a low resistance insulating layer) having a small conduction band offset with respect to the silicon substrate is interposed between the silicon substrate 102 and the buried contact 138 according to some embodiments of the inventive concept, a Fermi level depinning phenomenon between the silicon substrate 102 and the buried contact 138 may occur. That is, an effect in which a Schottky barrier between the silicon substrate 102 and the buried contact 138 is lowered, may be obtained. In other words, a contact resistance between the silicon substrate 102 and the buried contact 138 may be improved. Since the low resistance insulating layer 134 having a small conduction band offset is used between the second source/drain area SD2 and the buried contact 138 of the silicon substrate 102 of FIGS. 2A to 2C using these characteristics, the buried contact 138 may be used as a conductive metal material. Therefore, problems involving the above-described phenomena shown when the buried contact 138 is formed of polysilicon may be reduced. Further, since a contact resistance characteristic may be improved without increasing the doping concentration, a leakage current may be reduced. In this case, a thickness of the low resistance insulating layer 134 may have at a level which does not cause a resistance problem. For example, the low resistance insulating layer 134 may be formed to have a thickness level of a mono layer.

The low resistance insulating layer 134 may include, for example, titanium oxide (TiO₂), tantalum oxide (Ta₂O₅), or zirconium oxide (ZnO). The buried contact barrier layer 136 may include a barrier metal such as titanium (Ti), titanium nitride (TiN), tantalum (Ta), tantalum nitride (TaN), ruthenium (Ru), ruthenium nitride (RuN), or tungsten nitride (WN). The buried contact 138 may include a conductive metal material including titanium nitride (TiN). The conductive metal material may include, for example, tungsten (W).

The memory device 100a in accordance with some embodiments of the inventive concept may further include storage capacitors SC. For example, the storage capacitor SC may have a pillar shape. The storage capacitor SC may include a first storage electrode 154, a dielectric layer 156, and a second storage electrode 158. The first storage electrode 154 may be electrically connected to the buried contact 138 and the low resistance insulating layer 134.

An etch stop layer 148 may be formed to cover upper surfaces of the buried contact 138, the bit line side wall spacer 126, and the bit line capping layer 122. The first storage electrode 154 may be formed to pass through the etch stop layer 148 and may contact the upper surface of the buried contact 138. The first storage electrode 154 may protrude from an upper surface of the etch stop layer 148.

The first storage electrode 154 may include, for example, polysilicon, a conductive metal, or a conductive metal compound, which includes impurities. The dielectric layer 156 may include, for example, a material having a high dielectric constant such as ZrO, LaO, HfO, NbO, TaO, TiO, SrTiO, or SrTaO. The second storage electrode 158 may include, for example, a conductive metal or a conductive metal compound. The etch stop layer 148 may include, for example, silicon nitride (SiNₓ).

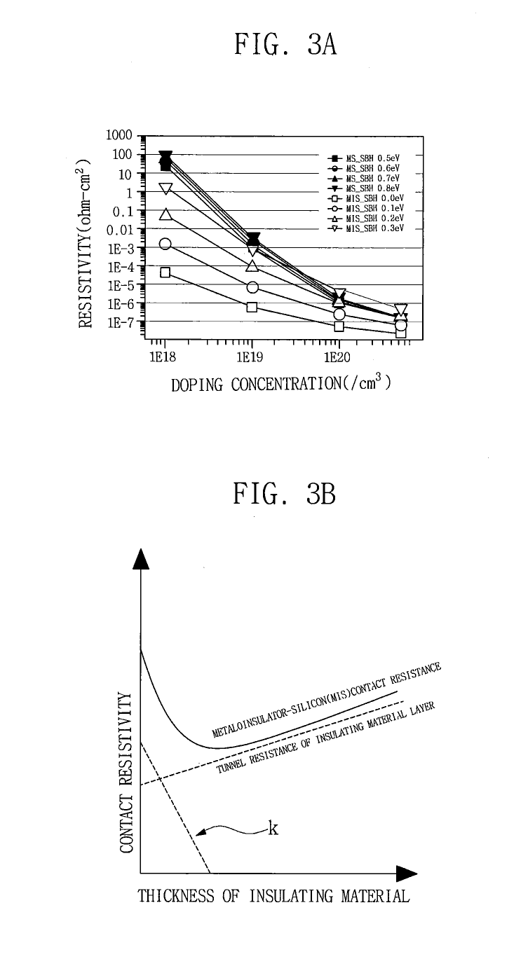

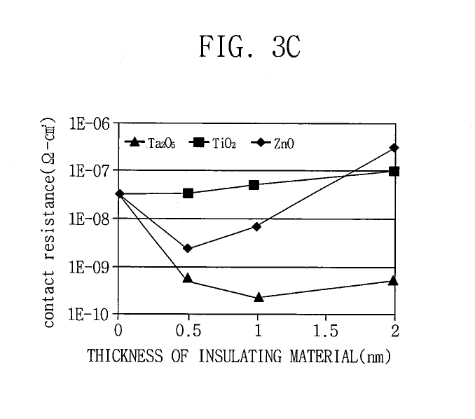

Hereinafter, a physical characteristic of a metal-insulator-semiconductor (MIS) contact including a low resistance insulating layer in accordance with some embodiments of the inventive concept will be described with reference to FIGS. 3A, 3B, and 3C. Hereinafter, semiconductor may be understood as “a silicon substrate,” an insulator may be understood as the above-described “low resistance insulating layer,” and a metal may be understood as “a buried contact.”

FIG. 3A is a graph showing resistivity of metal-semiconductor (MS) contacts and metal-insulator-semiconductor (MIS) contacts, of which Schottky barrier heights (SHB) are different, according to doping concentrations thereof. An X-axis of the graph shows a doping concentration, and a Y-axis of the graph shows resistivity. Samples include four types of MS contacts having different levels of SHB (0.5 eV, 0.6 eV, 0.7 eV, and 0.8 eV), and four types of MIS contacts having different levels of SHB (0.0 eV, 0.1 eV, 0.2 eV, and 0.3 eV). The doping concentration may be understood as a concentration of impurities included in a semiconductor. In this case, the resistivity may be understood as contact resistivity.

Referring to FIG. 3A, all the resistivity of all MIS contacts and MS contacts tend to be reduced as the doping concentration increases. However, when the MIS samples and the MS samples are compared at the same doping concentration, the resistivity of the MIS samples tends to be lower than that of the MS samples. Specifically, when the MIS samples are compared at the same doping concentration, a resistance value is reduced by approximately 1 order as the SBH of the contact is reduced. In this case, the SBH is more reduced as an insulating material layer has a small conduction band offset value with respect to a semiconductor layer.

Through the above-described tendency, the resistivity of the MIS contact, in which the low resistance insulating layer having a small conduction band offset with respect to semiconductor is interposed between contacts of the metal and the semiconductor, is smaller than that of the MS contact. With this characteristic, the MIS contacts may have the same existing value of the contact resistance without increasing a doping concentration compared to the MS contacts. That is, a contact resistance characteristic may be improved in comparison with the MS contact. Therefore, a leakage current characteristic may be improved. In this case, a thickness of the insulating material layer may have a level which does not cause a resistance problem as described above. It will be described below.

FIG. 3B is a graph showing a change of contact resistivity according to a thickness of an insulating material layer. An X-axis of the graph shows a change of the thickness of the insulating material layer, and a Y-axis of the graph shows a change of the contact resistivity.

Referring to FIG. 3B, contact resistance of an MIS contact may be changed according to the thickness of the insulating material layer, however, the contact resistance of the MIS contact should not be dramatically changed even though the thickness of the insulating material layer is changed to have a predetermined value or less. To this end, the insulating material layer may be formed to have a thickness in which tunneling resistance is not dramatically changed.

Therefore, the thickness of the insulating material layer may have a level which does not cause a problem in the contact resistance of the MIS contact. That is, an effect, in which the contact resistance of the MIS contact is reduced, may be obtained by a Fermi level depinning effect, shown as a dotted line indicated by k, unless the insulating material layer is not formed to have a predetermined thickness or greater. The insulating material in accordance with some embodiments of the inventive concept having this characteristic may include titanium oxide (TiO₂), tantalum oxide (Ta₂O₅), or zirconium oxide (ZnO).

Hereinafter, a contact resistance characteristic of the MIS contact according to thicknesses of the above-described insulating materials will be described with reference to FIG. 3C.

FIG. 3C is a graph showing a contact resistance characteristic of an MIS contact according to a thickness of an insulating material layer in accordance with some embodiments of the inventive concept.

Referring to FIG. 3C, the thickness of the insulating material (titanium oxide (TiO₂), tantalum oxide (Ta₂O₅), or zirconium oxide (ZnO)) layer may be a thickness which does not affect the contact resistance between a semiconductor and a metal. It will be understood that when the contact resistance of the MIS contact including the insulating material is less than or equal to IE-07, the MIS contact may have an advantage.

As shown, titanium oxide (TiO₂), tantalum oxide (Ta₂O₅), or zirconium oxide (ZnO) may have the contact resistance of IE-07 or less even though the thickness of the insulating material layer is changed to have a predetermined value or less, for example, 2 nm or less. Therefore, when the low resistance insulating layer described with reference to FIGS. 2A to 2C is formed to have the thickness which maintains the above-described contact resistance value using the above-described insulating materials, the contact resistance of the MIS contact may be reduced.

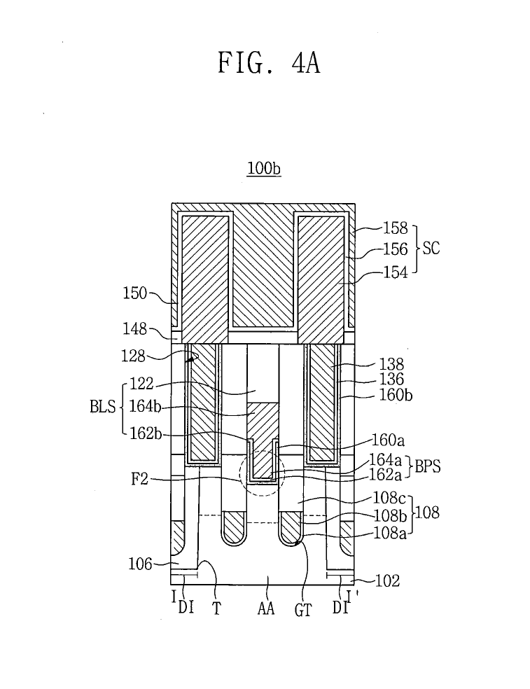

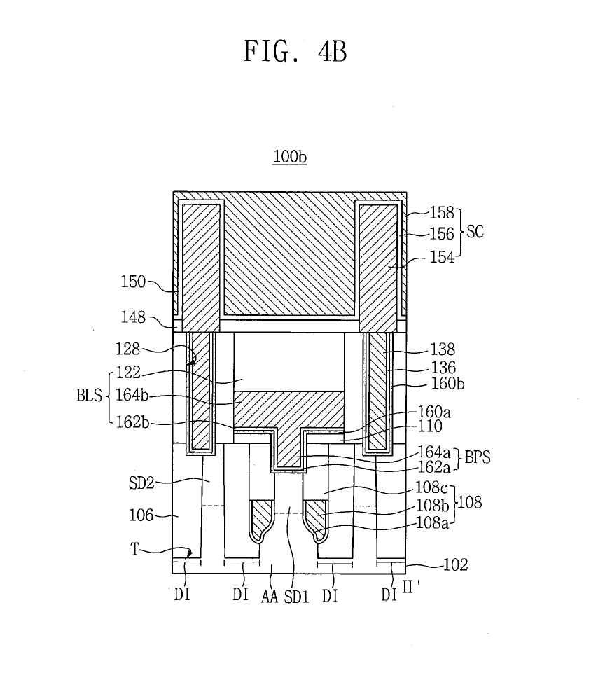

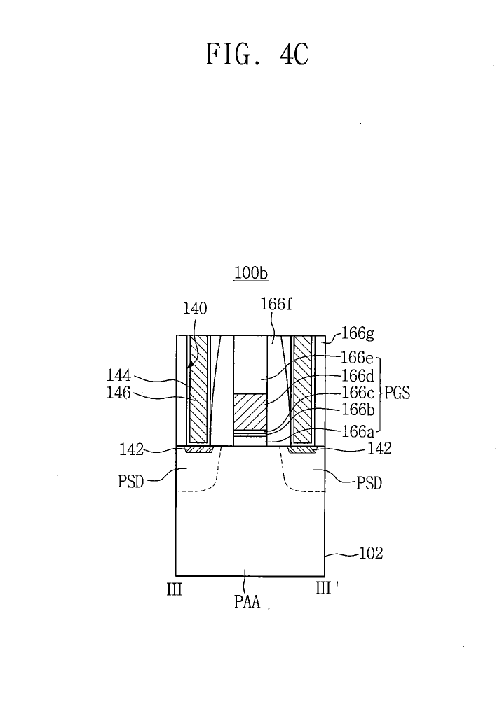

According to some embodiments, MIS contacts may be applied to the silicon substrate and the buried contact as described in FIG. 1, and to a bit plug as described below. It will be described with reference to FIGS. 4A to 4C.

FIGS. 4A and 4B are cross-sectional views of a memory device taken along the lines I-I′ and II-II′ of FIG. 1 and FIG. 4C is a cross-sectional view of the memory device taken along the line III-III′ of FIG. 1.

Referring to FIGS. 4A, 4B, 4C, and FIG. 1 the memory device 100b in accordance with some embodiments of the inventive concept may include a substrate 102 including a cell area CA and a peripheral area PA, gate line stacks 108, a first low resistance insulating layer 160a, a bit plug structure BPS, a second low resistance insulating layers 160b, a bit line stack BLS, buried contacts 138, and storage capacitors SC, which are formed in the cell area CA, and a peripheral gate electrode stack PGS and source/drain contacts 146, which are formed in the peripheral area PA.

The cell area CA may include an active area AA and a device isolation area DI. Trenches T which are formed by recessing a surface of the substrate 102 and an isolation layer 106 which fills the trenches T may be formed in the device isolation area DI. For example, the active area AA may have a bar shape which extends in one direction, and the bar-shaped active area AA may be disposed in the cell area CA to have a constant gradient. For example, a first source/drain area SD1 may be formed at a center of the active area AA in longitudinal direction of the active area AA and second source/drain areas SD2 may be formed at one end and another end of the active area AA, respectively.

Gate trenches GT may be formed to cross the device isolation area DI and the active area AA. The gate trenches GT may be filled with the gate line stacks 108. The adjacent gate line stacks 108 may cross any bar-shaped active area AA. The first source/drain area SD1 may include doping impurities at a concentration higher than the second source/drain area SD2. For example, the impurities may include N-type impurities. In some embodiments, the first source/drain area SD1 and the second source/drain area SD2 may include a doped semiconductor material and may be devoid of silicide. In some embodiments, upper surfaces of the first and second source/drain areas SD1 and SD2 may be devoid of silicide, the first low resistance insulating layer 160a may contact the upper surface of the first source/drain area SD1, and the second low resistance insulating layer 160b may contact the upper surface of the second source/drain area SD2.

The gate line stack 108 may include a gate insulating layer 108a which covers an inner wall of the gate trench GT, a gate line 108b which contacts the gate insulating layer 108a and fills a part of the gate trench GT, and a gate capping layer 108c which is formed on the gate line 108b and fills the remainder of the gate trench GT. The gate insulating layer 108a, the gate line 108b and the gate capping layer 108c may be sequentially stacked on the substrate 102.

The bit line stack BLS may be formed on the bit plug structure BPS in one body. The bit line stack BLS and the bit plug structure BPS may have a unitary structure and thus may be contiguous each other. A first interlayer insulating layer 110 may be formed under the bit line stack BLS. The first low resistance insulating layer 160a may be formed along a recessed surface of the first source/drain area SD1 and a surface of the first interlayer insulating layer 110. In some embodiments, the first low resistance insulating layer 160a may contact the surface of the first source/drain area SD1. Specifically, the first low resistance insulating layer 160a may contact the doped semiconductor material in the first source/drain area SD2. The bit line stack BLS and the bit plug stack BPS may be formed on a surface of the first low resistance insulating layer 160a.

The bit line stack BLS may include a bit line barrier layer 162b, a bit line 164b, and a bit line capping layer 122, which are sequentially stacked. The bit plug barrier layer 162a and the bit line barrier layer 162b may be formed as one body. The bit plug barrier layer 162a and the bit line barrier layer 162b may have a unitary structure. A bit plug 164a and the bit line 164b may be formed as one body. The bit plug 164a and the bit line 164b may have a unitary structure. Bit line side wall spacers 126 may be formed at side walls of the bit line stack BLS.

Buried contact holes 128 which expose surfaces of the second source/drain areas SD2 may be formed. Inner walls of the buried contact holes 128 each may be a side surface of the bit line side wall spacer 126. The second low resistance insulating layer 160b may be conformally formed along the surface of the second source/drain area SD2 and the inner walls of the buried contact hole 128. The buried contact 138 may contact the second low resistance insulating layer 160b and may fill the buried contact hole 128. A buried contact barrier layer 136 may be interposed between the second low resistance insulating layer 160b and the buried contact 138.

The peripheral gate electrode stack PGS may include a gate insulating layer 166a, a first gate barrier layer 166b, a second gate barrier layer 166c, a gate electrode 166d, and a gate capping layer 166e. Peripheral gate electrode side wall spacers 166f may be formed on side surfaces of the peripheral gate electrode stack PGS. A protection layer 166g may cover the peripheral gate electrode stack PGS. Source/drain contact holes 140 may be formed through the protection layer 166g. A bottom of the source/drain contact hole 140 may be the surface of the substrate 102. The surface of the substrate 102 may include peripheral source/drain areas PSD which are doped with impurities. Source/drain contacts 146 may contact the peripheral source/drain areas PSD. A silicide layer 142 may be formed between the peripheral source/drain area PSD and the source/drain contact 146. A source/drain contact barrier layer 144 may be further formed between the source/drain contact 146 and the peripheral source/drain area PSD.

The first low resistance insulating layer 160a, the second low resistance insulating layer 160b, and the first gate barrier layer 166b each may include, for example, titanium oxide (TiO₂), tantalum oxide (Ta₂O₅), or zirconium oxide (ZnO). The bit plug barrier layer 162a, the bit line barrier layer 162b, and the second gate barrier layer 166c each may include, for example, titanium (Ti), tantalum (Ta), tantalum nitride (TaN), tungsten nitride (WN), titanium nitride (TiN), or another barrier metal. The bit plug 164a, the bit line 164b and the gate electrode 166d each may include, for example, tungsten (W), aluminum (Al), copper (Cu), or nickel (Ni). The bit line capping layer 122 and the gate capping layer 166e each may include, for example, silicon nitride (SiNₓ). The bit line side wall spacer 126 and the peripheral gate electrode side wall spacer 166f each may include, for example, silicon nitride (SiNₓ).

The storage capacitor SC may have a pillar shape. The storage capacitor SC may include a first storage electrode 154, a dielectric layer 156, and a second storage electrode 158. The first storage electrode 154 may be electrically connected to the buried contact 138 and the second low resistance insulating layer 160b.

An etch stop layer 148 may be formed over upper surfaces of the buried contact 138, the bit line side wall spacer 126, and the bit line capping layer 122. The first storage electrode 154 may be formed to pass through the etch stop layer 148 and may contact a surface of the buried contact 138. The first storage electrode 154 may protrude from an upper surface of the etch stop layer 148.

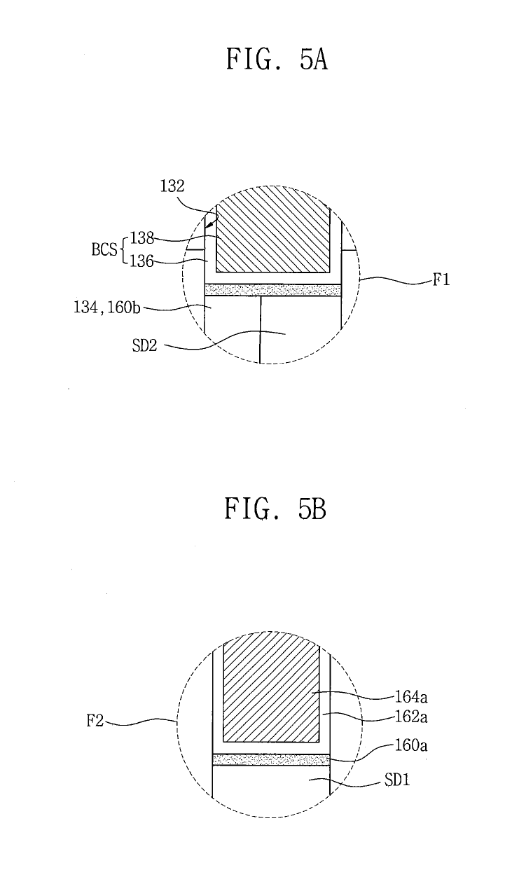

The low resistance insulating layer described in the above-described embodiments may be formed to be between the surface of the first source/drain area SD1 and a lower surface of the bit plug 164a and between the surface of the second source/drain area SD2 and a lower surface of the buried contact 138. It will be described with reference to FIGS. 5A to 5B.

FIG. 5A is an enlarged view of a part F1 in FIG. 2A and FIG. 5B is an enlarged view of a part F2 in FIG. 4A. Other forms of the above-described low resistance insulating layer will be described with reference to FIGS. 5A and 5B.

Referring to FIG. 5A, the low resistance insulating layer 134 of FIGS. 2A and 2B and the second low resistance insulating layer 160b of FIGS. 4A and 4B may be formed on the surface of the substrate 102 that is exposed through the buried contact hole 132. For example, the low resistance insulating layer 134 of FIGS. 2A and 2B and the second low resistance insulating layer 160b of FIGS. 4A and 4B may be formed between a bottom (e.g., a lower surface) of the buried contact hole 132 and the second source/drain area SD2.

Referring to FIG. 5B, the first low resistance insulating layer 160a of FIGS. 4A and 4B may be formed on the surface of the first source/drain area SD1. In this case, referring to FIG. 4C, the first gate barrier layer 166b of the peripheral gate electrode stacks PGS formed in the peripheral area PA may be omitted.

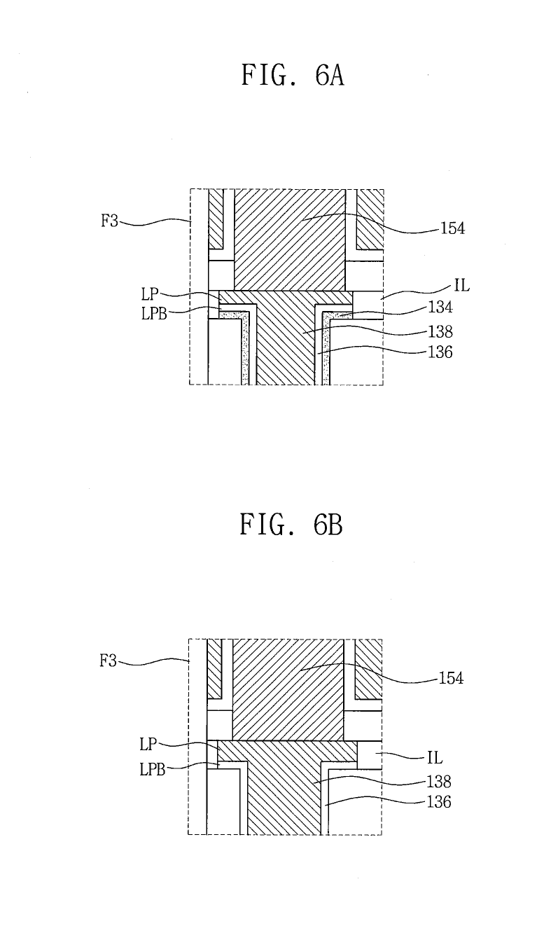

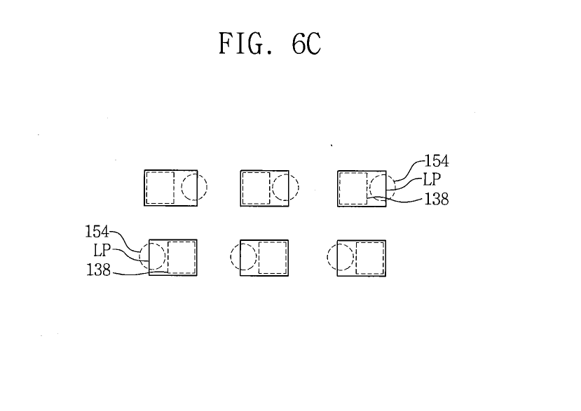

In some embodiments, a landing pad may be further interposed between the buried contact 138 and the storage capacitor SC. It will be described with reference to FIGS. 6A to 6C.

FIGS. 6A and 6B are enlarged views of a part F3 in FIG. 2A showing a structure including a landing pad between a buried contact and a first storage electrode. FIG. 6C is a plan view showing arrangements of the landing pad and the first storage electrode.

Referring to FIGS. 6A and 6B, the landing pad LP may be further included between the first storage electrode 154 and the buried contact 138. The landing pad LP may be formed on the buried contact 138 in one body. In some embodiments, the landing pad LP and the buried contact 138 may have a unitary structure and thus may be contiguous each other. A low resistance insulating layer 134 may be formed along surfaces of the buried contact 138 and the landing pad LP. A landing pad barrier layer LPB may be further formed between the landing pad LP and the low resistance insulating layer 134. An additional interlayer insulating layer IL may be formed to surround the landing pad LP.

In some embodiments, referring to FIG. 6B, the low resistance insulating layer 134 may be omitted. More specifically, the low resistance insulating layer 134 may be selectively formed between the bottom of the buried contact 138 and the second source/drain area SD2 as described in FIG. 5A, and may not be formed on a side of the buried contact 138.

Referring to FIG. 6C, the landing pad LP may be used as an intermediate electrode to electrically connect the first storage electrode 154 to the buried contact 138. A side of the landing pad LP may extend in a direction away from the buried contact 138. Centers of the first storage electrode 154 and the buried contact 138 may be arranged not aligned to each other. When a low resistance insulating layer 134 or 160b is formed on the landing pad LP, the low resistance insulating layer 134 or 160b may be vertically aligned with the landing pad LP according to a shape of the landing pad LP.

Hereinafter, a method of fabricating a memory device in accordance with some embodiments of the inventive concept will be described with reference to cross-sectional views. In this case, a process of forming a switching transistor formed in a peripheral area will be briefly described for convenience of descriptions.

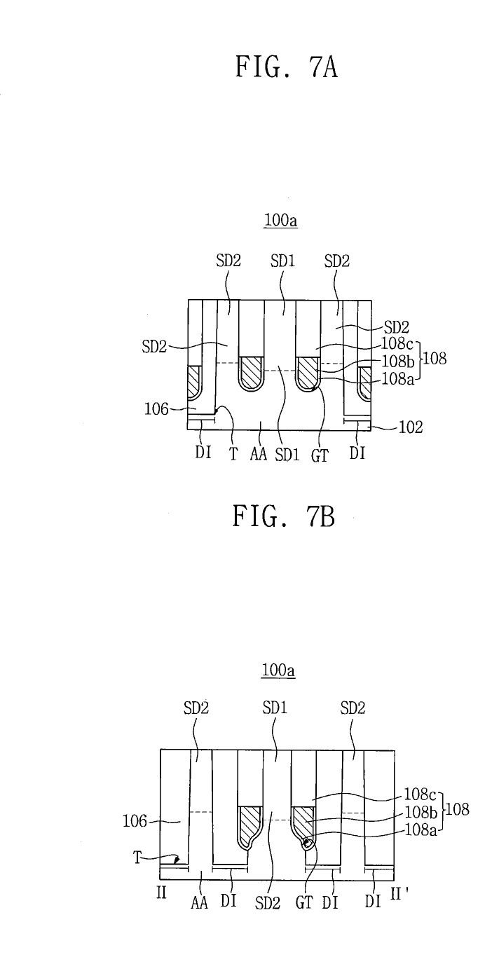

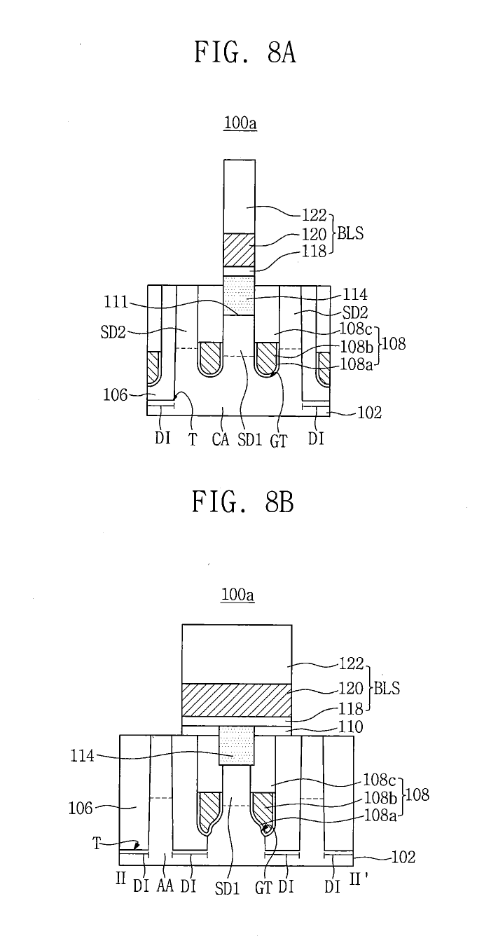

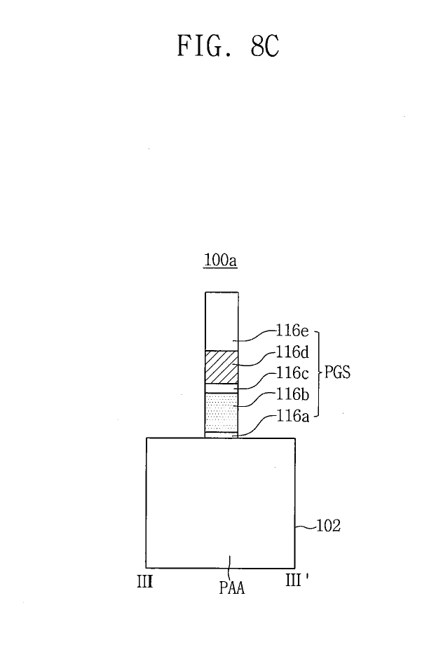

FIGS. 7A to 11A, FIGS. 7B to 11B, and FIGS. 8C to 11C are cross-sectional views showing a method of fabricating a memory device in accordance with some embodiments of the inventive concept. FIGS. 7A, 8A, 9A, 10A and 11A and FIGS. 7B, 8B, 9B, 10B and 11B are cross-sectional views of the memory device taken along the lines I-I′ and II-II′ of FIG. 1, respectively, and FIGS. 8C, 9C, 10C and 11C are cross-sectional views of the memory device taken along the line of FIG. 1.

Referring to FIGS. 1, 7A, and 7B, the method of fabricating the memory device 100a in accordance with some embodiments of the inventive concept may include forming trenches T, an isolation layer 106, gate trenches GT, and gate line stacks 108 on a substrate 102.

The substrate 102 may include a cell area CA and a peripheral area PA located around the cell area CA. The cell area CA may include a cell active area AA and a device isolation area DI, and the peripheral area PA may include a peripheral active area PAA and a peripheral device isolation area PDI. The trench T may be formed by recessing a surface of the substrate 102 corresponding to the device isolation area DI. The isolation layer 106 may fill the trenches T. Therefore, the isolation layer 106 may define shapes of the cell active areas AA and the peripheral active areas PAA. The cell active areas AA may have a bar shape which extends in one direction. The bar-shaped cell active areas AA may be uniformly arranged according to a design rule.

The gate trenches GT may extend in a first direction on the substrate 102. The gate trenches GT may be spaced apart from each other in a second direction that is perpendicular to the first direction. The gate trenches GT may be formed to cross the device isolation area DI and the cell active area AA. The gate trench GT may be filled with a gate line stack 108. The gate line stack 108 may include a gate insulating layer 108a, a gate line 108b, and a gate capping layer 108c, which are sequentially formed in the gate trench GT. A surface of the gate line 108b may be recessed to be lower than half of a depth of the gate trench GT.

The isolation layer 106 may include silicon oxide (SiO₂). The gate insulating layer 108a may include silicon oxide (SiO₂) or an insulating material having a high dielectric constant. For example, the gate line 108b may include tungsten (W). The gate capping layer 108c may include, for example, silicon nitride (SiNₓ).

The method may further include forming a first source/drain area SD1 and second source/drain areas SD2 by doping impurities into the cell active area AA. For example, the single cell active area AA may cross two gate line stacks 108. In this case, the first source/drain area SD1 and the second source/drain areas SD2 may be formed in the cell active areas AA exposed by the gate line stacks 108. The first source/drain area SD1 may be formed between the gate line stacks 108. The second source/drain areas SD2 may be formed to be adjacent to each side of the gate line stacks 108. For example, impurities included in the first and second source/drain areas SD1 and SD2 may include N-type impurities or P-type impurities. A concentration of the impurities in the first source/drain area SD1 may be greater than a concentration of the impurities in the second source/drain area SD2.

Referring to FIGS. 8A, 8B, and 8C, the method of fabricating the memory device 100a in accordance with some embodiments of the inventive concept may include forming an interlayer insulating layer 110, a bit plug 114, a bit line stack BLS, and a peripheral gate electrode stack PGS.

The bit plug 114 may pass through the first interlayer insulating layer 110 and may contact a recessed surface 111 of the first source/drain area SD1. The bit line stack BLS may include a bit line barrier layer 118, a bit line 120, and a bit line capping layer 122. The peripheral gate electrode stack PGS may include a gate insulating layer 116a, a first gate 116b, a gate barrier layer 116c, a second gate 116d, and a gate electrode capping layer 116e.

The interlayer insulating layer 110 and the gate insulating layer 116a may include, for example, silicon oxide (SiO₂). The bit plug 114 and the first gate 116b may include, for example, polysilicon. The bit line barrier layer 118 and the gate barrier layer 116c may include, for example, titanium (Ti), tantalum (Ta), tantalum nitride (TaN), tungsten nitride (WN), or titanium nitride (TiN). The bit line 120 and the second gate 116d may include, for example, tungsten (W), aluminum (Al), copper (Cu), or nickel (Ni). The bit line capping layer 122 and the gate electrode capping layer 116e may, for example, include silicon oxide (SiO₂).

A process of forming the peripheral gate electrode stack PGS in the peripheral area PA may be the same as the processes of forming the bit plug 114 and the bit line stack BLS in the cell area CA. For example, the process of forming the bit plug 114 may be the same as the process of forming the first gate 116b. The process of forming the bit line 120 may be the same as the process of forming the second gate 116d. Specifically, in a case of using the same processes, when the bit plug 114 and the first gate 116b are formed, impurities included in the bit plug 114 and the first gate 116b may have the same type or different types, and when the impurities thereof have different types, an additional process of doping with the impurities may be performed. The first gate 116b may be omitted in some embodiments.

The bit line capping layer 122 may be used as a hard mask layer for forming the bit line 120, the bit line barrier layer 118, and the first interlayer insulating layer 110. The gate electrode capping layer 116e may be used as a hard mask layer for forming the second gate 116d, the gate barrier layer 116c, a first gate 116b, and a gate insulating layer 116a formed thereunder.

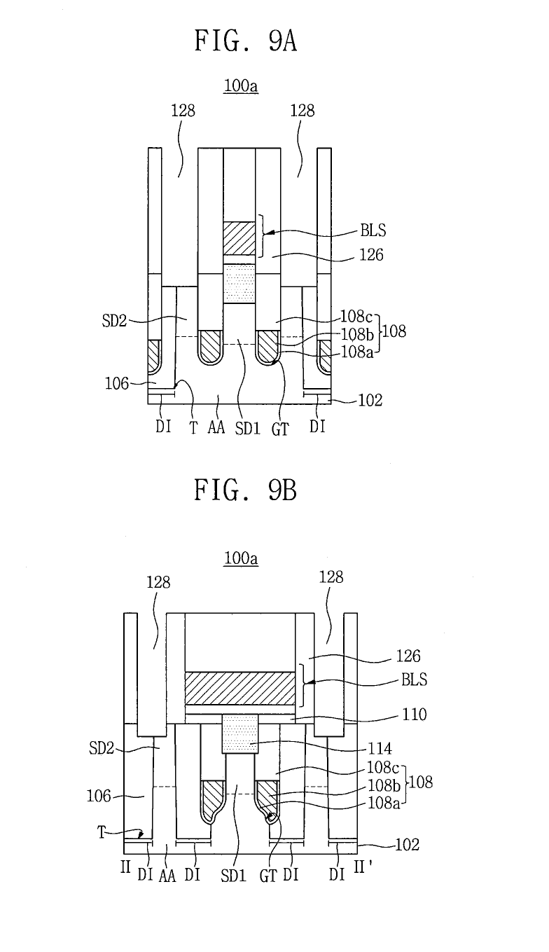

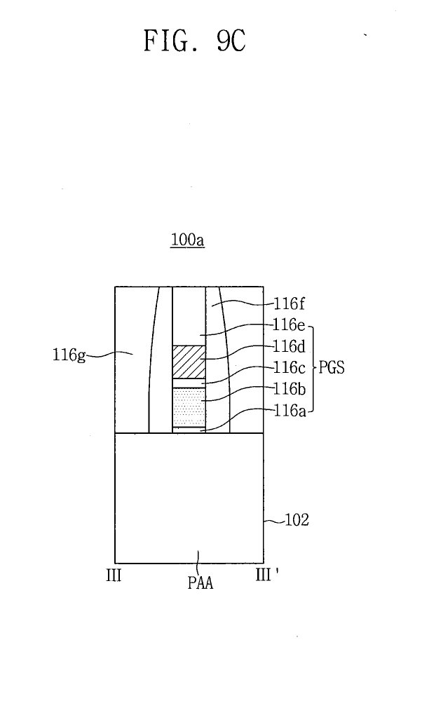

Referring to FIGS. 1, 9A, 9B, and 9C, the method of fabricating the memory device 100a in accordance with some embodiments of the inventive concept may include forming bit line side wall spacers 126, buried contact holes 128, and peripheral gate electrode side wall spacers 116f.

The bit line side wall spacer 126 may be formed along a side wall of the bit line stack BLS. The peripheral gate electrode side wall spacer 116f may be formed along a side surface of the peripheral gate electrode stack PGS. The buried contact hole 128 may be formed in a shared area which vertically crosses the gate line stack 108 and the bit line stack BLS. In some embodiments, the buried contact hole 128 may be formed in an area that is surrounded by adjacent gate line stacks 108 and adjacent bit line stacks BLS. Apart of a bottom of the buried contact hole 128 may be a surface of the second source/drain area SD2.

For example, the method of fabricating the memory device 100a in accordance with some embodiments of the inventive concept may include forming the bit line side wall spacers 126 after the peripheral gate electrode side wall spacers 116f are formed. The method may further include forming a protection layer 116g which covers the peripheral gate electrode side wall spacers 116f in the peripheral area PA. The bit line side wall spacer 126 may include, for example, silicon nitride (SiNₓ). The protection layer 116g may include, for example, silicon oxide (SiO₂).

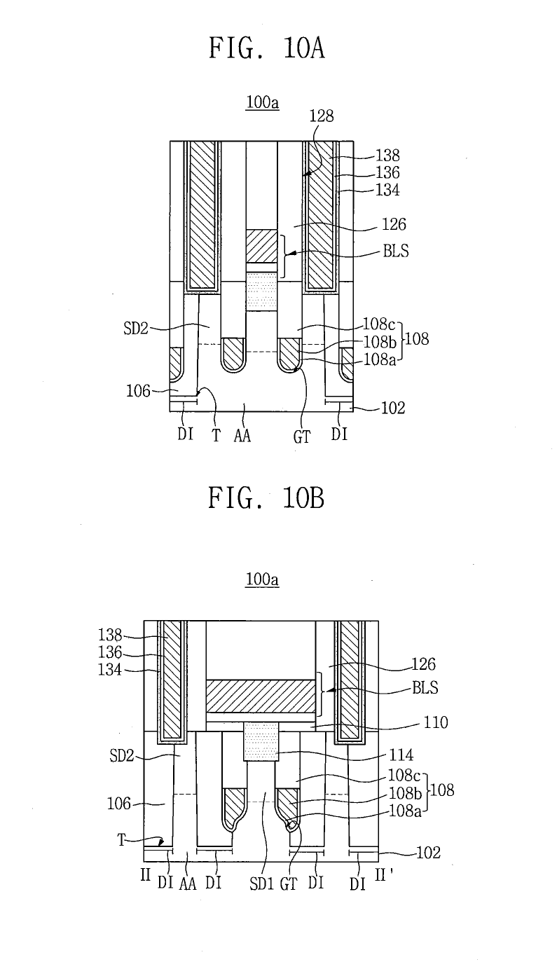

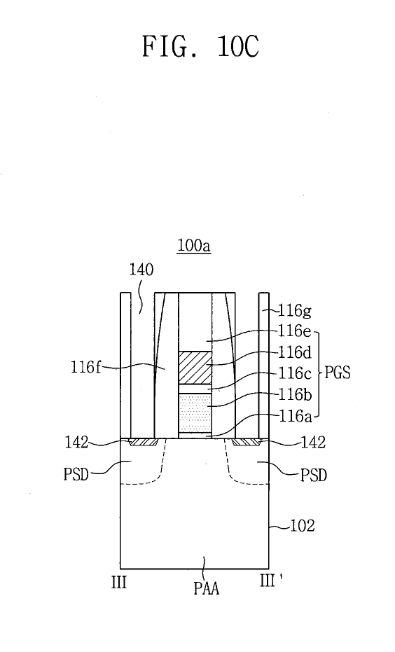

Referring to FIGS. 1, 10A, 10B, and 10C, the method of fabricating the memory device 100a in accordance with some embodiments of the inventive concept may include forming a low resistance insulating layer 134, a buried contact barrier layer 136, and a buried contact 138 inside the buried contact hole 128. The method may include forming source/drain contact holes 140, peripheral source/drain areas PSD, and silicide layers 142 in the peripheral area PA.

The low resistance insulating layer 134 may be conformally formed along an inner wall of the buried contact hole 128, and the buried contact barrier layer 136 may be conformally formed along a surface of the low resistance insulating layer 134. The buried contact 138 may be conformally formed along a surface of the buried contact barrier layer 136 and may fill the buried contact hole 128. In this process, the landing pad LP described with reference to FIGS. 6A and 6B may also be formed on the buried contact 138 in one body.

For example, the low resistance insulating layer 134 may include titanium oxide (TiO₂), tantalum oxide (Ta₂O₅), or zirconium oxide (ZnO). The buried contact barrier layer 136 may include, for example, titanium nitride (TiN). The buried contact 138 may include a conductive metal material. The conductive metal material may include, for example, tungsten (W).

As described above with reference to FIGS. 3A to 3C, the low resistance insulating layer 134 may include a material having a small conduction band offset with respect to the silicon substrate (or a semiconductor substrate). Since the low resistance insulating layer 134 has small tunneling resistance, a contact resistance characteristic between the surface of the second source/drain area SD2 which is the surface of the silicon substrate 102 and the buried contact 138 may be improved.

Therefore, since the contact resistance characteristic between the surfaces of the second source/drain area SD2 which is a silicon substrate and the buried contact barrier layer 136 (or the buried contact 138) is improved without increasing a concentration of the impurities in the second source/drain area SD2. Therefore, a leakage current may be reduced.

The forming of the source/drain contact holes 140 in the peripheral area PA may include exposing the surface of the substrate 102 adjacent to the peripheral gate electrode side wall spacers 116f by patterning the protection layer 116g. The forming of the peripheral source/drain areas PSD may include doping with impurities through the source/drain contact holes 140. The doping impurities may spread from the surface of the substrate 102 to a predetermined depth. The impurities may include N-type impurities or P-type impurities.

The forming of the silicide layer 142 may include applying heat after depositing a metal on a surface of the peripheral source/drain area PSD. The silicide layer 142 may include a layer which is formed so that the metal is spread from the surface of the silicon substrate 102 and combined with silicon of the substrate 102. The silicide layer 142 may include impurities of the same type as impurities included in the peripheral source/drain area PSD.

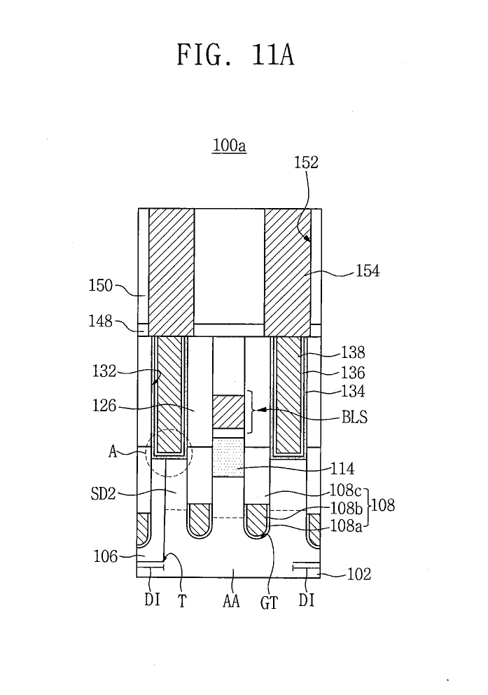

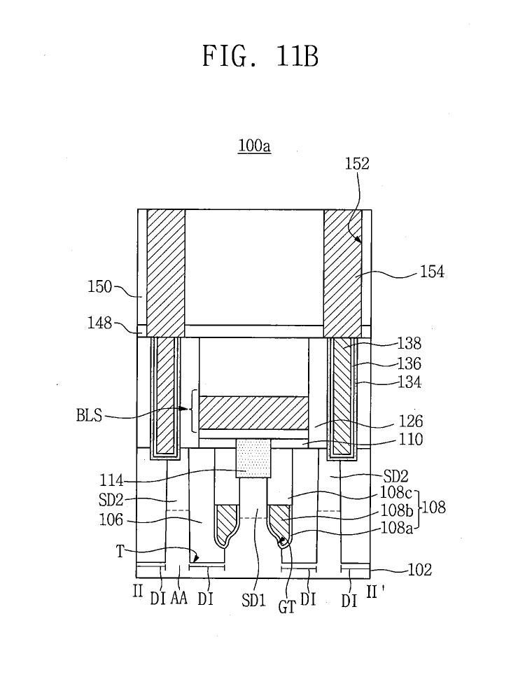

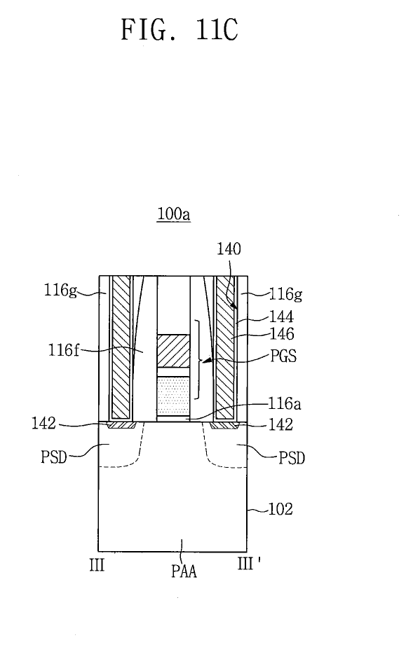

Referring to FIGS. 11A, 11B, and 11C, the method of fabricating the memory device 100a in accordance with some embodiments of the inventive concept may include forming source/drain contacts 146 in the peripheral area PA, and an etch stop layer 148, a second interlayer insulating layer 150, a storage contact hole 152, and a first storage electrode 154 in the cell area CA.

The source/drain contact 146 in the peripheral area PA may be formed to contact an upper surface of the silicide layer 142 and to fill the source/drain contact hole 140. The method may further include forming a source/drain contact barrier layer 144 on the upper surface of the silicide layer 142 and between an inner wall of the source/drain contact hole 140 and the source/drain contact 146.

The etch stop layer 148 in the cell area CA may cover the buried contact 138, the buried contact barrier layer 136, the low resistance insulating layer 134, and the bit line side wall spacers 126. The second interlayer insulating layer 150 may be stacked on a surface of the etch stop layer 148. The storage contact hole 152 may pass through the second interlayer insulating layer 150 and the etch stop layer 148. A bottom of the storage contact hole 152 may be an upper surface of the buried contact 138.

The source/drain contact barrier layer 144 may include, for example, titanium nitride (TiN). The source/drain contact 146 may include, for example, tungsten (W). The etch stop layer 148 may include, for example, silicon nitride (SiNₓ). The second interlayer insulating layer 150 may include, for example, silicon oxide (SiO₂). The first storage electrode 154 may include, for example, polysilicon, a conductive metal, or a conductive metal compound, which includes impurities.

In a subsequent process, referring to FIGS. 2A and 2B, the method of fabricating the memory device 100a in accordance with some embodiments of the inventive concept may include forming a storage capacitor SC.

The storage capacitor SC may include a first storage electrode 154, a dielectric layer 156 conformally formed along a surface of the first storage electrode 154, and a second storage electrode 158 which contacts a surface of the dielectric layer 156. The forming of the storage capacitor SC may include exposing the first storage electrode 154 on an upper part of the etch stop layer 148 by removing the second interlayer insulating layer 150. The method may include conformally forming the dielectric layer 156 along the exposed surface of the first storage electrode 154 and the surface of the etch stop layer 148. The method may include forming the second storage electrode 158 which contacts the dielectric layer 156.

The dielectric layer 156 may include a material having a high dielectric constant. For example, the material having a high dielectric constant may include ZrO, LaO, HfO, NbO, TaO, TiO, SrTiO, or SrTaO. The second storage electrode 158 may include a conductive metal or a conductive metal compound.

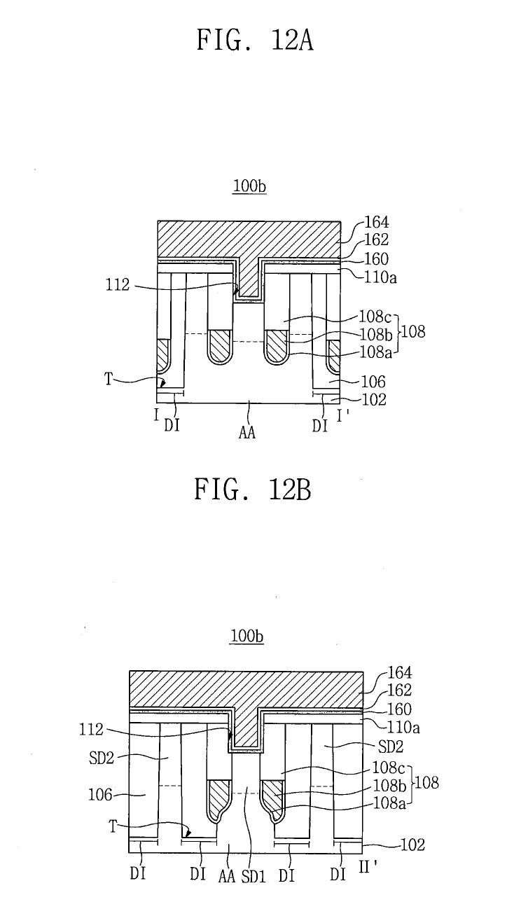

FIGS. 12A to 14A, FIGS. 12B to 14B, and FIGS. 13C to 14C are views showing a method of fabricating a memory device 100b in accordance with some embodiments of the inventive concept. FIGS. 12A, 13A and 14A, FIGS. 12B, 13B and 14B, and FIGS. 13C and 14C are cross-sectional views of the memory device 100b taken along the lines I-I′, and of FIG. 1, respectively.

Referring to FIGS. 1, 12A, and 12B, the method of fabricating the memory device 100b in accordance with some embodiments of the inventive concept may include forming trenches T, an isolation layer 106, gate trenches GT, gate line stacks 108, a first source/drain area SD1, and second source/drain areas SD2 on a substrate 102.

The substrate 102 may include a cell area CA and a peripheral area PA. An active area AA and a device isolation area DI may be formed in the cell area CA. The isolation layer 106 may fill the trench T. The gate line stack 108 may include a gate insulating layer 108a, a gate line 108b, and a gate capping layer 108c, which are sequentially formed in the gate trench GT. The gate line stack 108 may fill the gate trench GT. A concentration of impurities in the first source/drain area SD1 may be greater than a concentration of impurities in the second source/drain area SD2.

The method of fabricating the memory device 100b in accordance with some embodiments of the inventive concept may include forming a first interlayer insulating material layer 110a in the cell area CA, and forming bit plug contact holes 112 each of which passes through the first interlayer insulating material layer 110a and has a bottom that is a recessed surface of the first source/drain area SD1. The method of fabricating the memory device 100b in accordance with some embodiments of the inventive concept may include forming a low resistance material layer 160, a barrier material layer 162, and a conductive metal layer 164, which are conformally and sequentially stacked along the recessed surface of the first source/drain area SD1, an inner wall of the bit plug contact hole 112, and a surface of the first interlayer insulating material layer 110a.

The first interlayer insulating material layer 110a may include, for example, silicon oxide (SiO₂). The low resistance material layer 160 may include a material having a small conduction band offset with respect to the silicon substrate 102. The low resistance material layer 160 may include, for example, titanium oxide (TiO₂), tantalum oxide (Ta₂O₅), or zirconium oxide (ZnO). The barrier material layer 162 may include, for example, tantalum nitride (TaN), tungsten nitride (WN), or titanium nitride (TiN). The conductive metal layer 164 may include, for example, tungsten (W).

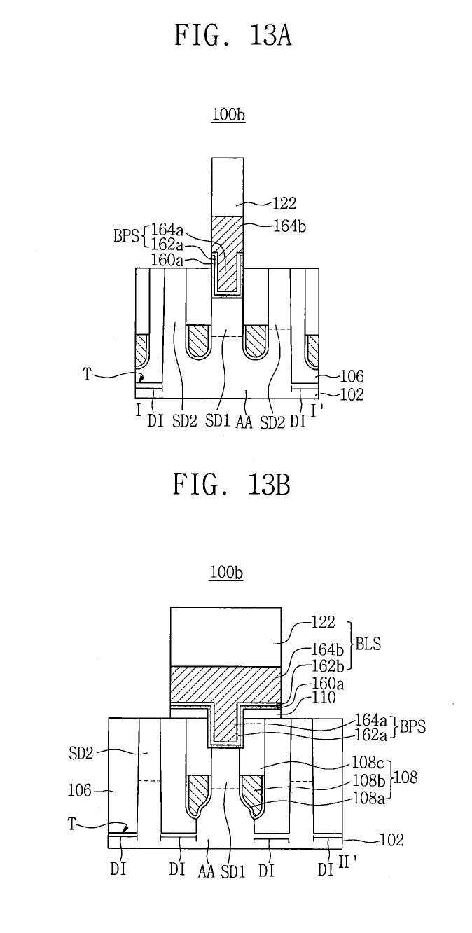

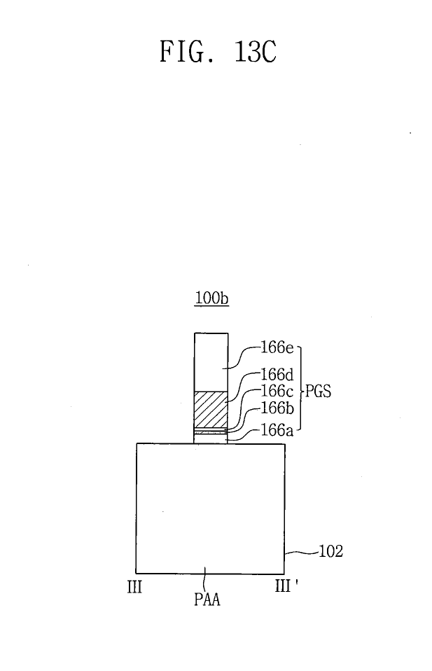

Referring to FIGS. 1, 13A, 13B, and 13C, the method of fabricating the memory device 100b in accordance with some embodiments of the inventive concept may include forming a first low resistance insulating layer 160a, a bit plug stack BPS, and a bit line stack BLS in the cell area CA, and forming a peripheral gate electrode stack PGS in the peripheral area PA.

The bit plug stack BPS may include a bit plug barrier layer 162a and a bit plug 164a. The bit line stacks BLS may include a bit line barrier layer 162b, a bit line 164b, and a bit line capping layer 122. The bit plug stack BPS and the bit line stack BLS may be formed as one body. The first low resistance insulating layer 160a may be conformally formed along the surface of the first source/drain area SD1, the inner wall of the bit plug contact hole 112, and the surface of the first interlayer insulating layer 110.

The peripheral gate electrode stack PGS may include a gate insulating layer 166a, a first gate barrier layer 166b, a second gate barrier layer 166c, a gate electrode 166d, and a gate capping layer 166e. For example, the peripheral gate electrode stack PGS may be formed using the same process as the bit plug stack BPS and the bit line stack BLS in the cell area CA. In this case, the first gate barrier layer 166b may be the same material as the first low resistance insulating layer 160a, the second gate barrier layer 166c may be the same material as the bit line barrier layer 162b and the bit plug barrier layer 162a, and the gate electrode 166d may be the same material as the bit line 164b and the bit plug 164a.

Since processes below are the same as the processes described with reference to FIGS. 9A to 11A, 9B to 11B, and 9C to 11C, it will be briefly described.

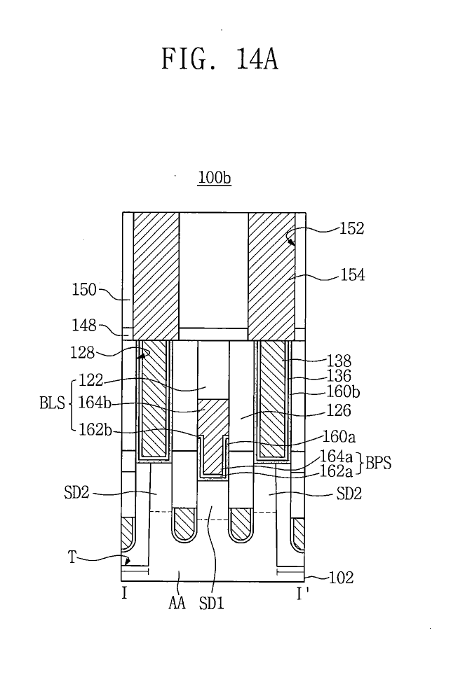

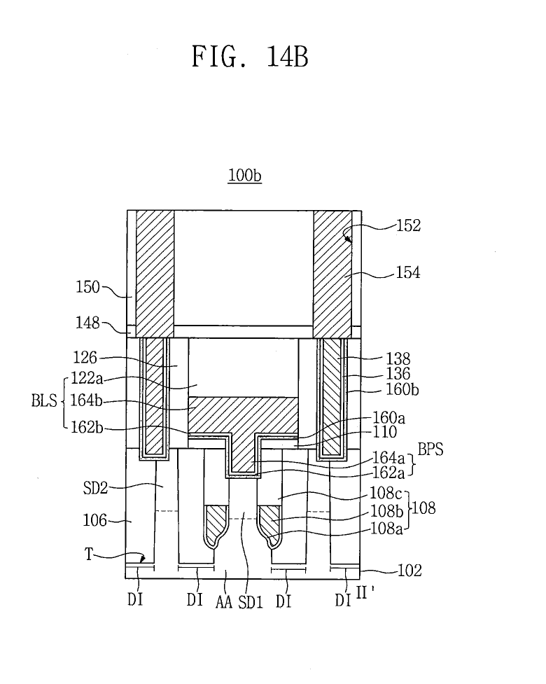

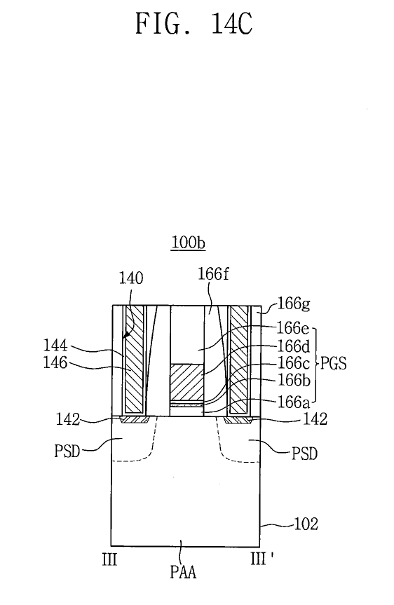

Referring to FIGS. 14A, 14B, and 14C, the method of fabricating the memory device 100b in accordance with some embodiments of the inventive concept may include forming bit line side wall spacers 126, buried contact holes 128, and peripheral gate electrode side wall spacers 166f.

The method of fabricating the memory device 100b in accordance with some embodiments of the inventive concept may include forming a second low resistance insulating layer 160b, a buried contact barrier layer 136, and a buried contact 138 in the buried contact hole 128. The second low resistance insulating layer 160b may be formed along the recessed surface of the second source/drain area SD2 and an inner wall of the buried contact hole 128. The buried contact barrier layer 136 may be formed along a surface of the second low resistance insulating layer 160b. The buried contact 138 may contact the second low resistance insulating layer 160b and fill the buried contact hole 128. The second low resistance insulating layer 160b may include, for example, titanium oxide (TiO₂), tantalum oxide (Ta₂O₅), or zirconium oxide (ZnO).

The peripheral gate electrode side wall spacer 166f may cover a side wall of the peripheral gate electrode stack PGS. A protection layer 166g may be formed to cover the peripheral gate electrode stack PGS and the peripheral area PA. Source/drain contact holes 140 may be formed to expose the surface of the substrate 102 through the protection layer 166g. Peripheral source/drain areas PSD doped with impurities may be formed on bottoms of the source/drain contact holes 140. The silicide layer 142 may be formed in the peripheral source/drain area PSD. The silicide layer 142 may include impurities, and the impurities may include the same type as that of the peripheral source/drain area PSD.

A source/drain contact barrier layer 144 may be formed along the surface of the silicide layer 142 and the inner wall of the source/drain contact hole 140. A source/drain contact 146 may be formed to contact a surface of the source/drain contact barrier layer 144 and fill the source/drain contact hole 140.

The method of fabricating the memory device 100b in accordance with some embodiments of the inventive concept may include forming a first storage electrode 154 in the cell area CA. The first storage electrode 154 may contact the buried contact 138. The first storage electrode 154 may be formed through an etch stop layer 148 and a second interlayer insulating layer 150.

In the subsequent process, referring to FIGS. 4A and 4B, the method of fabricating the memory device 100b in accordance with some embodiments of the inventive concept may include forming a storage capacitor SC.

The storage capacitor SC may include a first storage electrode 154, a dielectric layer 156 conformally formed along a surface of the first storage electrode 154, and a second storage electrode 158 which contacts a surface of the dielectric layer 156. The forming of the storage capacitor SC may include exposing the first storage electrode 154 on an upper part of the etch stop layer 148 by removing the second interlayer insulating layer 150. The method may include conformally forming the dielectric layer 156 along the exposed surface of the first storage electrode 154 and the surface of the etch stop layer 148. The method may include forming the second storage electrode 158 which contacts the dielectric layer 156.

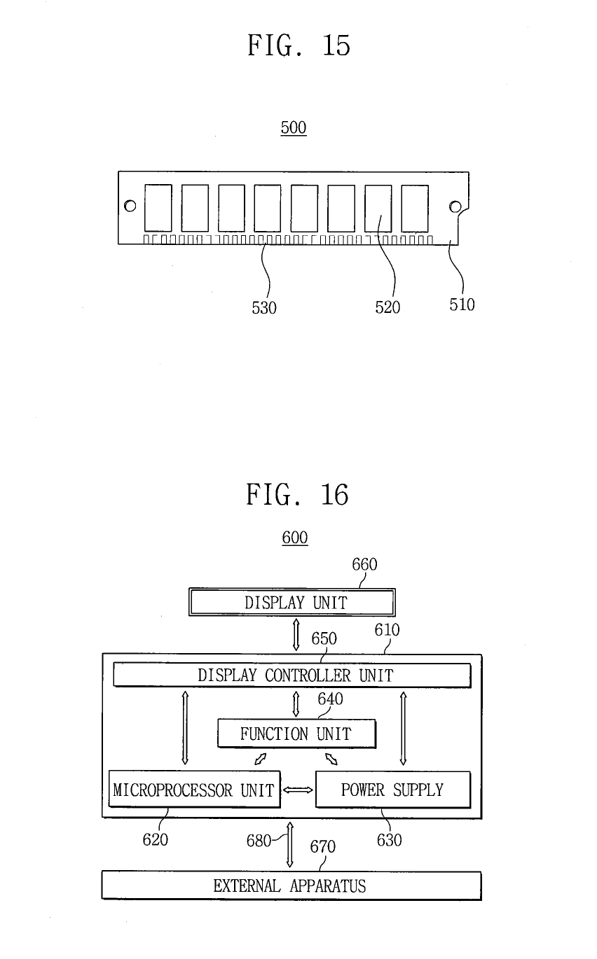

FIG. 15 is a module including a memory device according to some embodiments of the inventive concept. Referring to FIG. 15, the module 500 may include the memory devices 100a and 100b in accordance with the embodiments of the inventive concept mounted on a module substrate 510. The module 500 may further include a microprocessor 520 mounted on the module substrate 510. Input/output terminals 530 may be disposed on at least one side of the module substrate 510.

FIG. 16 is a block diagram of an electronic system including a memory device according to some embodiments of the inventive concept.

Referring to FIG. 16, the memory devices 100a and 100b fabricated according to some embodiments of the inventive concept may be applied to the electronic system 600. The electronic system 600 may include a body 610, a microprocessor unit 620, a power supply 630, a function unit 640, and/or a display controller unit 650. The body 610 may be a system board or a motherboard having a PCB, etc. The microprocessor unit 620, the power supply 630, the function unit 640, and the display controller unit 650 may be installed or mounted on the body 610. A display unit 660 may be disposed on an upper surface of the body 610 or outside the body 610. For example, the display unit 660 may be disposed on a surface of the body 610, and display an image processed by the display controller unit 650. The power supply 630 may receive a constant voltage from an external power supply, divide the voltage into various voltages levels, and supply those voltages to the microprocessor unit 620, the function unit 640, the display controller unit 650, etc. The microprocessor unit 620 may receive a voltage from the power supply 630 to control the function unit 640 and the display unit 660. The function unit 640 may perform various functions of the electronic system 600. For example, when the electronic system 600 is a mobile electronic product such as a cellular phone, etc., the function unit 640 may include various components which perform wireless communication functions such as dialing, image output to the display unit 660, or voice output to a speaker through communication with an external apparatus 670, and when a camera is included, it may serve as an image processor. In some embodiments, when the electronic system 600 is connected to a memory card to expand the capacity, the function unit 640 may be a memory card controller. The function unit 640 may exchange signals with the external apparatus 670 through a wired or wireless communication unit 680. Further, when the electronic system 600 requires a Universal Serial Bus (USB) to extend the functions, the function unit 640 may serve as an interface controller. The memory devices 100a and 100b fabricated according to the embodiments of the inventive concept may be included in the function unit 640.

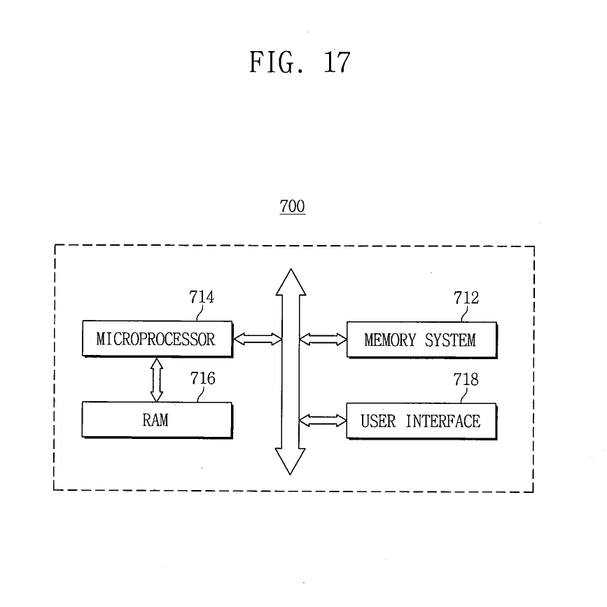

FIG. 17 is a schematic block diagram of an electronic system including a memory device according to some embodiments of the inventive concept.

Referring to FIG. 17, the electronic system 700 may include the memory devices 100a and 100b according to some embodiments of the inventive concept.

The electronic system 700 may be applied to a mobile device or a computer. For example, the electronic system 700 may include a memory system 712, a microprocessor 714, a RAM 716, and a user interface 718, which perform data communication using a bus. The microprocessor 714 may program and control the electronic system 700. The RAM 716 may be used as an operational memory of the microprocessor 714. For example, the microprocessor 714 and the RAM 716 may include one of the memory devices 100a and 100b in accordance with some embodiments of the inventive concept. The microprocessor 714, the RAM 716, and/or other components may be assembled within a single package. The user interface 718 may be used to input data to the electronic system 700, or output data from the electronic system 700. The memory system 712 may store operational codes of the microprocessor 714, data processed by the microprocessor 714, or data received from the outside. The memory system 712 may include a controller and a memory.

According to memory devices in accordance with some embodiments of the inventive concept, a low resistance insulating layer may be interposed between a metal buried contact and a silicon substrate. Therefore, a Fermi level depinning effect, in which a Schottky barrier between the metal buried contact and the silicon substrate is lowered, may be obtained.

Since a contact resistance between the silicon substrate and the metal buried contact maybe reduced by the Fermi level depinning effect, a contact resistance characteristic may be improved without increasing a concentration of impurities. Therefore, a leakage current of a transistor may be reduced or possibly minimized.

Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims.

1. A memory device, comprising:
an active area including a source/drain area in a substrate;
a gate line crossing the active area;
a low resistance insulating layer contacting an upper surface of the source/drain area;
a contact on the upper surface of the source/drain area, the contact contacting the low resistance insulating layer and including a conductive metal; and
a storage capacitor electrically connected to the contact.

2. The device of claim 1, wherein the low resistance insulating layer comprises a metal oxide having a small conduction band offset with respect to the source/drain area.

3. The device of claim 2, wherein the low resistance insulating layer comprises titanium oxide (TiO₂), tantalum oxide (Ta₂O₅), or zirconium oxide (ZnO).

4. The device of claim 1, further comprising a barrier layer between the low resistance insulating layer and the contact.

5. The device of claim 1, wherein the low resistance insulating layer is between a lower surface of the contact and the upper surface of the source/drain area.

6. The device of claim 1, wherein the upper surface of the source/drain area contacting the low resistance insulating layer is devoid of silicide.

7.-9. (canceled)

10. The device of claim 1, wherein the source/drain area comprises a first source/drain area adjacent a first side of the gate line, and the low resistance insulating layer comprises a first low resistance insulating layer contacting an upper surface of the first source/drain area, and
wherein the device further comprises:
a second source/drain area adjacent a second side of the gate line;
a bit line plug on the second source/drain area, the bit plug comprising a conductive metal; and
a second low resistance insulating layer between the bit line plug and the second source/drain area.

11. The device of claim 10, further comprising a bit line, wherein the bit line plug and the bit line has a unitary structure, and the second low resistance insulating layer contacts the bit line plug and the bit line.

12.-22. (canceled)

23. The memory device of claim 1, further comprising a peripheral active area in a peripheral area of the substrate, wherein the peripheral active area includes a peripheral source/drain area and a silicide layer in the peripheral source/drain area.

24.-26. (canceled)

27. An integrated circuit device comprising:
an active area in a substrate;
a gate electrode in the active area;
a source/drain area adjacent a side of the gate electrode in the active area, the source/drain area comprising a doped semiconductor material;
an interlayer insulating layer on the active area, the interlayer insulating layer comprising a recess that exposes an upper surface of the source/drain area;
a conductive plug that is in the recess and comprises a first metal; and
an insulating layer that is in the recess and comprises a second metal, the insulating layer extending between the upper surface of the source/drain area and a lower surface of the conductive plug and contacting the doped semiconductor material.

28. The device of claim 27, wherein the insulating layer comprises titanium oxide (TiO₂), tantalum oxide (Ta₂O₅), or zirconium oxide (ZnO).

29. The device of claim 28, wherein a thickness of the insulating layer in a vertical direction that is perpendicular to the upper surface of the source/drain area is less than about 2 nm.

30. The device of claim 27, wherein the source/drain area comprises a first source/drain area adjacent a first side of the gate electrode,
wherein the device further comprises a second source/drain area adjacent a second side of the gate electrode, and
wherein a dopant concentration of the first source/drain area is lower than a dopant concentration of the second source/drain area.

31. The device of claim 30, further comprising a storage capacitor comprising an electrode, wherein the conductive plug is electrically connected to the electrode of the storage capacitor.

32. The device of claim 27, wherein the upper surface of the source/drain area is devoid of silicide.

33. The device of claim 27, wherein the source/drain area comprises a first source/drain area adjacent a first side of the gate electrode, the recess comprises a first recess that is in the interlayer insulating layer and exposes an upper surface of the first source/drain area, the conductive plug comprises a first conductive plug in the first recess, the insulating layer comprises a first insulating layer that is in the first recess, and
wherein the device further comprises:
a second source/drain area adjacent a second side of the gate electrode;
a second recess that is in the interlayer insulating layer and exposes an upper surface of the second source/drain area;
a second conductive plug that is in the second recess and comprises a third metal; and
a second insulating layer that is in the second recess and comprises a fourth metal, the second insulating layer extending between the upper surface of the second source/drain area and a lower surface of the second conductive plug and contacting the upper surface of the second source/drain area.

34. The device of claim 33, wherein the second insulating layer comprises titanium oxide (TiO₂), tantalum oxide (Ta₂O₅), or zirconium oxide (ZnO).

35. The device of claim 33, further comprising a bit line, wherein the second conductive plug is electrically connected to the bit line.

36. The device of claim 27, further comprising a barrier layer that comprises a barrier metal and is between the insulating layer and the conductive plug.

37. The device of claim 27, wherein the insulating layer is on an inner sidewall of the recess.
